(19) United States
(12) Patent Application Publication
(10) Pub. No.: US 2026/0161174 A1
(43) Pub. Date: Jun. 11, 2026

(54) Article Transport Facility

(71) Applicant: Daifuku Co., Ltd., Osaka-shi (JP)

(72) Inventors: Keisuke Takeno, Komaki-shi (JP); Makoto Kono, Komaki-shi (JP); Kazuhiro Iwamitsu, Komaki-shi (JP)

(21) Appl. No.: 19/181,190

(22) Filed: Apr. 16, 2025

(30) Foreign Application Priority Data
Apr. 17, 2024 (JP) 2024-066980

(51) Int. Cl. G05D 1/644; G05D 1/225; G05D 105/28; G05D 107/70; H10P 72/30

(52) U.S. Cl. CPC G05D 1/644; G05D 1/225; H10P 72/3216; G05D 2105/28; G05D 2107/70; H10P 72/3214

(57) ABSTRACT

An article transport facility includes a control system. The control system executes: route extraction processing for extracting a plurality of candidate routes by referring to map information; cost correction amount deriving processing for deriving a cost correction amount for each of the plurality of candidate routes based on a combination of shapes of a plurality of links included in the candidate route; and route selection processing for selecting a candidate route having the smallest route cost out of the plurality of candidate routes, as a movement route of a transport vehicle, by calculating a route cost of each candidate route based on a sum of standard costs of all links included in the candidate route R and the cost correction amount determined for that candidate route in the cost correction amount deriving processing.

### CROSS-REFERENCE TO RELATED APPLICATION

This application claims priority to Japanese Patent Application No. 2024-066980 filed Apr. 17, 2024, the disclosure of which is hereby incorporated by reference in its entirety.

### BACKGROUND OF THE INVENTION

### 1. Field of the Invention

The present invention relates to an article transport facility that includes a predetermined route, a transport vehicle that travels along the route and transports an article, and a control system that designates a movement destination and a movement route to the movement destination with respect to the transport vehicle.

### 2. Description of Related Art

For example, WO 2023/132101 discloses a technology for selecting, as a movement route of a transport vehicle, a route having the smallest cost among a plurality of routes from a start point to a destination.

In the technology disclosed in WO 2023/132101, the cost of a curved route is set to be higher than the cost of a straight route, and the movement route of the transport vehicle is selected to minimize the total cost of the route from the start point to the destination.

In technologies for selecting a movement route such that the total cost of the route is minimized as disclosed in WO 2023/132101 described above, other than costs that dynamically change, such as a congestion degree, the cost of the movement route is usually calculated by adding up link costs set in advance for respective links. The link costs of the links are set to different values depending on whether the shape of each link is straight or curved. However, even if the sum of link costs set for respective links is the same, the shape of a route formed by the plurality of links varies depending on the arrangement order of the plurality of links (e.g., the arrangement order of a plurality of straight links and a plurality of curved links), for example. The ease of travel of the transport vehicle varies according to the shape of such a route formed by a plurality of links. Conventional technologies have room for improvement from the viewpoint of selecting an appropriate route taking the shape of the route formed by a plurality of links into consideration.

### SUMMARY OF THE INVENTION

In view of the above circumstances, there are demands for a technology that enables selection of an appropriate route taking the shape of the route formed by a plurality of links into consideration.

The following is a technology for solving the above problems.

An article transport facility including:
a predetermined route;
a transport vehicle configured to travel along the route and transport an article; and
a control system configured to designate, with respect to the transport vehicle, a movement destination and a movement route to the movement destination,
wherein the route includes a plurality of nodes and a plurality of links connecting adjacent nodes among the nodes to each other,
the article transport facility is configured to set in advance, for each of the plurality of links, a standard cost corresponding to a time it takes for the transport vehicle to pass through that link, and
the control system is configured to execute:
route extraction processing for extracting a plurality of candidate routes that are candidates for the route along which the transport vehicle is capable of moving from a movement origin to the movement destination by referring to map information that is information regarding the route;
cost correction amount deriving processing for deriving, with respect to each of the plurality of candidate routes, a cost correction amount of the candidate route based on a combination of shapes of the plurality of links included in the candidate route; and
route selection processing for selecting a candidate route having a smallest route cost out of the plurality of candidate routes, as the movement route of the transport vehicle, by calculating a route cost of each candidate route based on a sum of the standard costs of all links included in the candidate route and the cost correction amount determined for that candidate route in the cost correction amount deriving processing.

According to this configuration, the cost correction amount is derived for each candidate route based on the combination of shapes of a plurality of links included in the candidate route, and the route cost is calculated with use of the cost correction amount. In the calculation of the route cost described above, the shape of the candidate route formed by the plurality of links is taken into consideration in addition to the standard costs set for the respective links. Therefore, according to this configuration, it is possible to select an appropriate route in the route selection processing taking the shape of the route formed by the plurality of links into consideration.

Further features and advantages of the technology according to the present disclosure will be further clarified by the following description of a non-limiting illustrative embodiment referring to the drawings.

### BRIEF DESCRIPTION OF THE DRAWINGS

FIG. 1 is a plan view showing a part of an article transport facility.

FIG. 2 is a flowchart showing a processing procedure of cost correction amount deriving processing.

FIG. 3 is a diagram showing a route cost of a first route.

FIG. 4 is a diagram showing a route cost of a second route.

FIG. 5 is a diagram showing a route cost of a third route.

### DESCRIPTION OF THE INVENTION

The following describes an embodiment of an article transport facility with reference to the drawings.

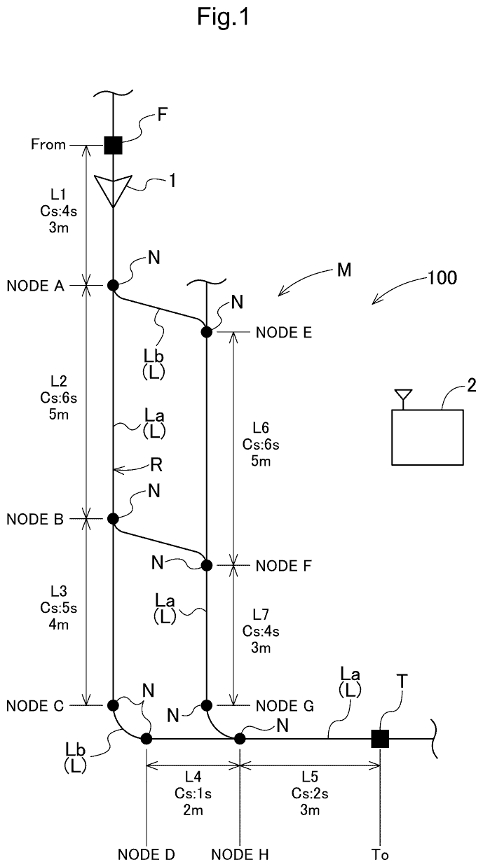

As shown in FIG. 1, an article transport facility 100 includes a predetermined route R, a transport vehicle 1 that travels along the route R and transports an article (not shown), and a control system 2 that designates, with respect to the transport vehicle 1, a movement destination T and a movement route to the movement destination T.

In the present embodiment, the route R is formed using a rail. For example, the rail forming the route R is installed in the vicinity of the ceiling of the facility. In this case, the transport vehicle 1 is configured as a so-called overhead transport vehicle that travels along the route R installed in the vicinity of the ceiling.

Various articles can be handled by the article transport facility 100. For example, the article transport facility 100 may be used for a semiconductor manufacturing factory. Accordingly, examples of the articles include substrate housing containers (so-called FOUPs: Front Opening Unified Pods) for housing substrates (wafers, panels, etc.), reticle housing containers (so-called reticle pods) for housing reticles, magazines, and trays. In this case, the transport vehicle 1 transports articles such as substrate housing containers or reticle housing containers along the route R between processes.

Although details are not illustrated, the article transport facility 100 includes a plurality of transfer target locations to or from which the transport vehicle 1 transfers articles. The plurality of transfer target locations are arranged along the route R. The transfer target locations are locations to which the transport vehicle 1 transfers articles or from which the transport vehicle 1 receives articles. Examples of the transfer target locations include a processing port provided in a device for processing semiconductor substrates, a buffer for temporarily storing articles midway on the route R, and an inlet port and an outlet port provided adjacent to an automated warehouse for storing the articles.

The control system 2 includes a storage device for storing information input to an input device, an arithmetic processing device that performs arithmetic processing by reading information from the storage device and stores results of the processing in the storage device, and a control device that gives commands to these devices. The control system 2 is configured to include one or more CPUs. The CPUs are elements included in a stationary control device installed in the facility or a control device installed on the transport vehicle 1.

The control system 2 gives a transport command to the transport vehicle 1. The transport command includes information on the current position of the transport vehicle 1 that is the target of the command, and information on a transport origin (start point) and a transport destination (end point) of an article. Upon receiving the transport command, the transport vehicle 1 moves from the current position to the transport origin to receive the article relating to the transport command, and after receiving the article, the transport vehicle 1 transports the article from the transport origin to the transport destination. Examples of the transport origin and the transport destination include the transfer target locations described above.

As described above, the control system 2 designates a movement destination T and a movement route to the movement destination T with respect to the transport vehicle 1. The movement route is a route R from a movement origin F of the transport vehicle 1 to the movement destination T. The transport command described above also includes information on the movement route. The movement origin F is the current position of the transport vehicle 1 that is the target of the command, or a transfer target location at which the article to be transported is located. The movement destination T is a transfer target location at which the article to be transported is located, or a transfer target location to which the article to be transported is to be transported.

For example, the control system 2 sets a transfer target location at which the article to be transported is located, as the movement destination T, and designates a movement route from the current position (movement origin F) of the transport vehicle 1 to the movement destination T to the transport vehicle 1 to let the transport vehicle 1 holding no article to receive the article. Alternatively, the control system 2 sets a transfer target location at which the article to be transported is located, as the movement origin F, sets a transfer target location to which the article is to be transported, as the movement destination T, and designates a movement route from the movement origin F to the movement destination T to the transport vehicle 1.

As shown in FIG. 1, the route R includes a plurality of nodes N and a plurality of links L connecting adjacent nodes N to each other. In FIG. 1, the plurality of nodes N are denoted by “A” to “H” and the plurality of links L are denoted by “L1” to “L7”. In the following description, the specific nodes N will be referred to as “node A”, “node B”, etc., and also referred to as “nodes N” when they are not distinguished from each other. Also, the specific links L will be referred to as “link L1”, “link L2”, etc., and also referred to as “links L” when they are not distinguished from each other.

In the present embodiment, the links L include straight links La and curved links Lb. The straight links La are linear links L. The curved links Lb are links L having curved shapes. The curved links Lb are links L that at least have a radius of curvature smaller than that of the straight links La. In this example, if at least a portion of a single link L has a curved shape, the link L is classified into the curved links Lb. For example, an N-shaped link L connecting the node A and the node E in the diagram is classified into the curved links Lb because a portion of the link L branching from another link L and a portion of the link L joining another link L have curved shapes.

Each node N is a branching point or a joining point on the route R or a boundary point between a straight link La and a curved link Lb.

A standard cost Cs corresponding to the time it takes for the transport vehicle 1 to pass through the link L is set in advance for each of the plurality of links L. The standard cost Cs is a fixed value that is set for each link L based on the length of the link L, the structure of the link L, or the environment surrounding the link L, such as the presence or absence of stations (transfer target locations). In this example, the unit of the standard cost Cs is “seconds [s]”. In the present embodiment, a straight line distance is set for each straight link La. The straight line distance is the length of the straight link La. The standard cost Cs of each straight link La is set based on at least the straight line distance. Thus, the standard cost Cs of each straight link La can be set appropriately.

The control system 2 is configured to be capable of referring to map information M that is information regarding the route R. The map information M includes the shape of each link L included in the route R, a connection relationship between the links L, the standard cost Cs of each link L, and the length (e.g., with the unit of meter [m]) of each link L, for example. The map information M is stored in a database (not shown), for example. The control system 2 obtains the map information M from the database, and executes various types of processing based on the map information M. When the map information M is updated through processing performed by the control system 2, the updated map information M is stored again in the database.

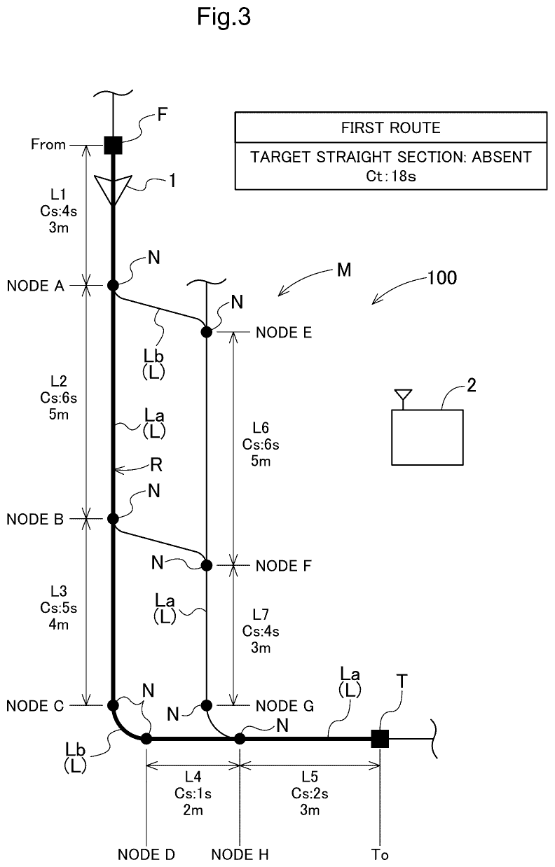

The layout shown in FIG. 1 includes a plurality of routes R from the movement origin F to the movement destination T. The control system 2 selects the most reasonable route R from these routes R as a movement route to be taken by the transport vehicle 1. The route R is selected based on a route cost Ct (see FIG. 3, etc.) calculated for each route R.

The control system 2 executes route extraction processing for extracting a plurality of candidate routes R that are candidates for the route R along which the transport vehicle 1 can move from the movement origin F to the movement destination T by referring to the map information M, which is information regarding the routes R.

Also, the control system 2 executes cost correction amount deriving processing for deriving a cost correction amount Cc (see FIG. 3, etc.) for each of the plurality of candidate routes R based on a combination of shapes of a plurality of links L included in the candidate route R.

Furthermore, the control system 2 executes route selection processing for selecting a candidate route R having the smallest route cost Ct out of the plurality of candidate routes R, as the movement route of the transport vehicle 1 by calculating the route cost Ct of each candidate route R based on the sum of standard costs Cs of all links L included in the candidate route R and the cost correction amount Cc determined for each candidate route R in the cost correction amount deriving processing.

That is to say, the control system 2 calculates the route cost Ct of each candidate route R with use of the cost correction amount Cc determined in the cost correction amount deriving processing, rather than calculating the route cost Ct simply from the standard costs Cs of the links L. This makes it possible to select an appropriate route.

Note that the standard cost Cs is not set for the curved links Lb in the present embodiment. In the present embodiment, only the costs of the straight links La are taken into consideration. That is to say, the control system 2 calculates the route cost Ct based on only the costs of the straight links La in the route selection processing. The travel speed of the transport vehicle 1 is likely to be relatively constant under any conditions when the transport vehicle 1 travels along a curved link Lb. Accordingly, if the transport vehicle 1 passes through the same curved link Lb, the time it takes for the transport vehicle 1 to pass through the curved link Lb is relatively constant irrespective of which route R is selected. Therefore, the costs of the curved links Lb are ignorable. For this reason, it is possible to eliminate cost calculation with low necessity in the present embodiment, and accordingly, reasonable route selection can be performed. However, the description of the present specification does not exclude configurations in which the route cost Ct is calculated taking also the costs of the curved links Lb into consideration.

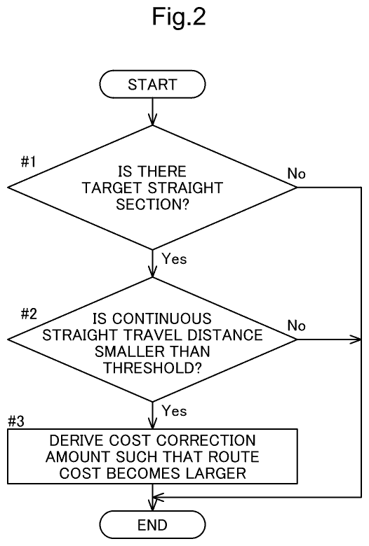

FIG. 2 shows a processing procedure of the cost correction amount deriving processing.

In the present embodiment, a section in which one or more straight links La are arranged continuously between two curved links Lb in each candidate route R will be referred to as a “target straight section SA”, and the length of this section will be referred to as a “continuous straight travel distance DA”.

In the cost correction amount deriving processing, first, whether or not the candidate route R includes a target straight section SA is determined (step #1). If it is determined that the candidate route R includes a target straight section SA (step #1: Yes), whether or not the length of the target straight section SA, i.e., the continuous straight travel distance DA is smaller than a threshold X is determined (step #2).

If it is determined that the continuous straight travel distance DA is smaller than the threshold X (step #2: Yes), a cost correction amount Cc is derived such that the route cost Ct of the candidate route R becomes larger (step #3). That is to say, the cost correction amount Cc is derived in the cost correction amount deriving processing such that, if the candidate route R includes a target straight section SA whose continuous straight travel distance DA is smaller than the predetermined threshold X, the route cost Ct of the candidate route R becomes larger than the route cost of a candidate route R that does not include a target straight section SA whose continuous straight travel distance DA is smaller than the threshold X. Accordingly, the candidate route R has a relatively large route cost Ct, and is unlikely to be selected as the movement route from the movement origin F to the movement destination T of the transport vehicle 1.

In the present embodiment, if it is determined in step #1 that the candidate route R does not include a target straight section SA (step #1: No), the cost correction amount Cc is set to zero. Also, if it is determined in step #2 that any continuous straight travel distance DA is equal to or larger than the threshold X (step #2: No), the cost correction amount Cc is set to zero.

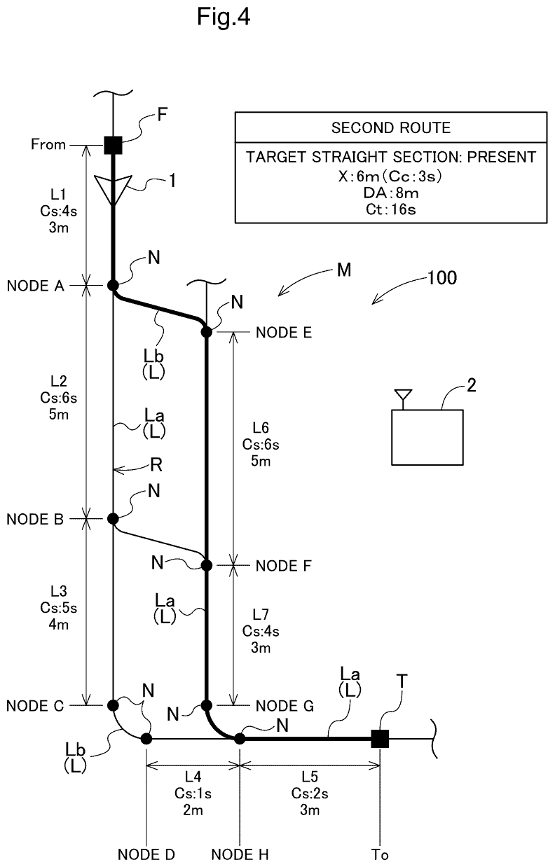

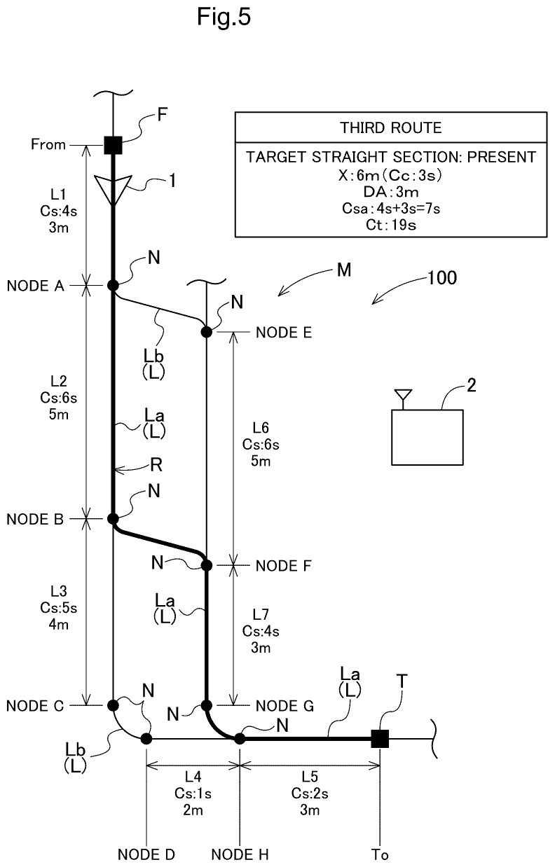

The following specifically describes calculation of the route costs Ct of candidate routes R with reference to FIGS. 3 to 5. The layout shown in FIG. 1 includes a total of three candidate routes R from the movement origin F to the movement destination T. Out of these candidate routes R, FIG. 3 shows a first route, FIG. 4 shows a second route, and FIG. 5 shows a third route. As described above, in this example, the control system 2 can extract the first route, the second route, and the third route in the route extraction processing.

As shown in FIG. 3, the first route is a route R including the nodes A, B, C, D, and H arranged in this order between the movement origin F and the movement destination T. In this case, the first route includes links L1, L2, L3, L4, and L5.

First, whether or not the first route includes a target straight section SA is determined. The first route shown in FIG. 3 includes only a curved link Lb between the node C and the node D, and does not include any other curved link Lb. The condition for determining the presence of a target straight section SA in the candidate route R (hereinafter referred to as a “target straight section present condition”) is that the candidate route R includes at least two curved links Lb and a straight link La sandwiched between these curved links Lb. The first route shown in FIG. 3 includes only one curved link Lb, and accordingly, does not satisfy the above condition. Therefore, the first route does not include a target straight section SA, and the cost correction amount Cc of this case is set to zero in the present embodiment as described above.

The route cost Ct of the first route is calculated by merely adding up standard costs Cs of the links L included in the first route. In this example, the route cost Ct of the first route is calculated to be “18 s” (4 s+6 s+5 s+1 s+2 s=18 s) by adding up the standard cost Cs “4s” of the link L1, the standard cost Cs “6s” of the link L2, the standard cost Cs “5s” of the link L3, the standard cost Cs “1s” of the link L4, and the standard cost Cs “2s” of the link L5.

As shown in FIG. 4, the second route is a route R including the nodes A, E, F, G, and H arranged in this order between the movement origin F and the movement destination T. In this case, the second route includes links L1, L6, L7, and L5.

First, whether or not the second route includes a target straight section SA is determined. The second route shown in FIG. 4 includes a curved link Lb between the nodes A and E and a curved link Lb between the nodes G and H. Also, the links L6 and L7, which are straight links La, are sandwiched between these two curved links Lb. Therefore, the second route shown in FIG. 4 satisfies the target straight section present condition. Accordingly, it is determined that the second route includes a target straight section SA.

The second route includes a target straight section SA, and accordingly, whether or not the continuous straight travel distance DA, which is the length of the target straight section SA, is smaller than the threshold X is determined next. The threshold X is a fixed value that is determined in advance through experiments or the like, but may also be a variable value that may vary according to operations of the facility or the situation at that time. In this example, the threshold X is a fixed value, and is set to “6 meters [m]”, for example.

In the second route shown in FIG. 4, the continuous straight travel distance DA of the target straight section SA including the links L6 and L7 is determined to be “8 m” by adding up the length “5 m” of the link L6 and the length “3 m” of the link L7 (5 m+3 m=8 m). Therefore, the continuous straight travel distance DA (8 m) in the second route is larger than the threshold X (6 m), and the cost correction amount Cc of this case is set to zero in the present embodiment as described above.

The route cost Ct of the second route is calculated by merely adding up standard costs Cs of the links L included in the second route. In this example, the route cost Ct of the second route is calculated to be “16 s” (4 s+6 s+4 s+2 s=16 s) by adding up the standard cost Cs “4 s” of the link L1, the standard cost Cs “6 s” of the link L6, the standard cost Cs “4 s” of the link L7, and the standard cost Cs “2 s” of the link L5.

As shown in FIG. 5, the third route is a route R including the nodes A, B, F, G, and H arranged in this order between the movement origin F and the movement destination T. In this case, the third route includes links L1, L2, L7, and L5.

First, whether or not the third route includes a target straight section SA is determined. The third route shown in FIG. 5 includes a curved link Lb between the nodes B and F and a curved link Lb between the nodes G and H. Also, the link L7, which is a straight link La, is sandwiched between these two curved links Lb. Therefore, the third route shown in FIG. 5 satisfies the target straight section present condition. Accordingly, it is determined that the third route includes a target straight section SA.

The third route includes a target straight section SA, and accordingly, whether or not the continuous straight travel distance DA, which is the length of the target straight section SA, is smaller than the threshold X is determined next. As described above, the threshold X is set to “6 meters [m]” in this example.

In the third route shown in FIG. 5, the continuous straight travel distance DA of the target straight section SA including the link L7 is equal to the length of the link L7, which is “3 m”. Accordingly, the continuous straight travel distance DA is determined to be “3 m” (3 m=3 m). Therefore, the continuous straight travel distance DA (3 m) in the third route is smaller than the threshold X (6 m).

The cost correction amount Cc of the case where the continuous straight travel distance DA is smaller than the threshold X is set to be larger than the cost correction amount Cc (in this example, zero) of the case where the continuous straight travel distance DA is equal to or larger than the threshold X. Accordingly, in the present embodiment, the cost correction amount Cc of the case where the continuous straight travel distance DA is smaller than the threshold X is set to 1 second [s] or more. Here, the cost correction amount Cc of this case is a fixed value and is set to “3 s” in this example.

The route cost Ct of the third route is calculated based on standard costs Cs of the links L included in the third route and the cost correction amount Cc. In the present embodiment, the route cost Ct is calculated by adding the cost correction amount Cc to the sum of the standard costs Cs of the links L. In this example, the route cost Ct of the third route is calculated to be “19 s” (4 s+6 s+4 s+2 s+3 s=19 s) by adding the cost correction amount Cc “3 s” to the sum of the standard cost Cs “4 s” of the link L1, the standard cost Cs “6 s” of the link L2, the standard cost Cs “4s” of the link L7, and the standard cost Cs “2 s” of the link L5.

As described above, when the first through third routes shown in FIGS. 3 to 5 are candidate routes R, the second route having the smallest route cost Ct (route cost Ct=16 s) is selected as the movement route from the movement origin F to the movement destination T of the transport vehicle 1. Note that the route selection processing is performed while conceivable patterns of the route R from the movement origin F to the movement destination T are extracted successively. However, there is no limitation to this configuration, and it is also possible to perform the route selection processing by calculating the route cost Ct of each candidate route R after all candidate routes R from the movement origin F to the movement destination T have been extracted.

In the example described above, the second route and the third route each include only one target straight section SA. However, a candidate route R may include a plurality of target straight sections SA.

Therefore, in the cost correction amount deriving processing according to the present embodiment, the cost correction amount Cc is derived for each target straight section SA. The sum of standard costs Cs of all links L included in each target straight section SA is obtained as a target straight section standard cost Csa, and the route cost Ct of each candidate route R is calculated in the route selection processing based on a value obtained by correcting the target straight section standard cost Csa of each target straight section SA included in the candidate route R with the cost correction amount Cc derived for each target straight section SA. For example, the third route shown in FIG. 5 includes a target straight section SA, and the target straight section standard cost Csa of the target straight section SA that is corrected is determined to be “7 s” by adding the standard cost Cs “4 s” of the link L7 and the cost correction amount Cc “3 s”.

That is to say, in the present embodiment, if a candidate route R includes a plurality of target straight sections SA, the cost correction amount Cc is derived for each target straight section SA, and all the derived cost correction amounts Cc are reflected in the route cost Ct of the candidate route R. In this example, all the cost correction amounts Cc are added to calculate the route cost Ct.

### Other Embodiments

Next, the following describes other embodiments.
(1) In the above embodiment, an example is described in which the route cost Ct is calculated by adding the cost correction amount Cc to the sum of the standard costs Cs of the links L. However, there is no limitation to this example, and the route cost Ct may also be calculated by multiplying the sum of the standard costs Cs of the links L by the cost correction amount Cc. Note that the derived cost correction amount Cc may also be used for subtraction or division depending on the method for deriving the cost correction amount Cc.
(2) In the above embodiment, an example is described in which the cost correction amount Cc is derived in the cost correction amount deriving processing such that, if the candidate route R includes a target straight section SA whose continuous straight travel distance DA is smaller than the predetermined threshold X, the route cost Ct of the candidate route R becomes larger than the route cost of a candidate route R that does not include a target straight section SA whose continuous straight travel distance DA is smaller than the threshold X. However, there is no limitation to this example, and the cost correction amount Cc may also be derived with a logic opposite to the above logic. That is to say, the cost correction amount Cc may be derived in the cost correction amount deriving processing such that, if the candidate route R does not include a target straight section SA whose continuous straight travel distance DA is smaller than the predetermined threshold X, the route cost Ct of the candidate route R becomes smaller than the route cost of a candidate route R that includes a target straight section SA whose continuous straight travel distance DA is smaller than the threshold X. It is possible to make a candidate route R having a large cost unlikely to be selected with this configuration as well.
(3) In the above embodiment, an example is described in which the cost correction amount Cc of the case where the continuous straight travel distance DA is smaller than the threshold X is a fixed value (3 seconds [s] in the above example). However, there is no limitation to this example, and the cost correction amount Cc may be a value (fixed value+variable value) obtained by adding a variable value that is set according to the number of transport vehicles 1 (congestion degree) present on the links L at the point in time when the cost correction amount deriving processing is performed or a future point in time. Alternatively, the cost correction amount Cc may also be set based on a learned value based on the past operation results of the transport vehicle 1.
(4) In the above embodiment, an example is described in which the cost correction amount Cc varies depending on whether or not the continuous straight travel distance DA is smaller than the threshold X. However, there is no limitation to this example, and the cost correction amount Cc may also be a variable value that varies gradually or stepwise depending on the length of the continuous straight travel distance DA, irrespective of the threshold X.
(5) In the above embodiment, an example is described in which the transport vehicle 1 is configured as a so-called overhead transport vehicle that travels along a route R set in the vicinity of the ceiling. However, there is no limitation to this example, and the transport vehicle 1 may also be a guided cart or a trackless cart. If the transport vehicle 1 is a trackless cart (so-called AGV), the route R is preferably formed with use of a magnetic tape provided on the floor, a two-dimensional code holding positional information, or the like.
(6) The configurations disclosed in the above embodiment may also be applied in combination with the configurations disclosed in the other embodiments as long as no contradiction arises. The embodiments disclosed in the present specification including the other configurations are merely examples in all aspects. Accordingly, it is possible to make various alterations as appropriate within a scope not departing from the gist of the present disclosure.

### Summary of Present Embodiment

The following describes a summary of the present embodiment.

An article transport facility including:
a predetermined route;
a transport vehicle configured to travel along the route and transport an article; and
a control system configured to designate, with respect to the transport vehicle, a movement destination and a movement route to the movement destination,
wherein the route includes a plurality of nodes and a plurality of links connecting adjacent nodes among the nodes to each other,
the article transport facility is configured to set in advance, for each of the plurality of links, a standard cost corresponding to a time it takes for the transport vehicle to pass through that link, and
the control system is configured to execute:
route extraction processing for extracting a plurality of candidate routes that are candidates for the route along which the transport vehicle is capable of moving from a movement origin to the movement destination by referring to map information that is information regarding the route;
cost correction amount deriving processing for deriving, with respect to each of the plurality of candidate routes, a cost correction amount of the candidate route based on a combination of shapes of the plurality of links included in the candidate route; and
route selection processing for selecting a candidate route having a smallest route cost out of the plurality of candidate routes, as the movement route of the transport vehicle, by calculating a route cost of each candidate route based on a sum of the standard costs of all links included in the candidate route and the cost correction amount determined for that candidate route in the cost correction amount deriving processing.

According to this configuration, the cost correction amount is derived for each candidate route based on the combination of shapes of a plurality of links included in the candidate route, and the route cost is calculated using this cost correction amount. In the calculation of the route cost described above, the shape of the candidate route formed by the plurality of links is taken into consideration in addition to the standard costs set for the respective links. Therefore, according to this configuration, it is possible to select an appropriate route in the route selection processing taking the shape of the route formed by the plurality of links into consideration.

It is preferable that the links include one or more straight links and one or more curved links, and
the cost correction amount is derived in the cost correction amount deriving processing such that, if a candidate route includes a target straight section whose continuous straight travel distance is smaller than a predetermined threshold, the route cost of that candidate route becomes larger than the route cost of a candidate route that does not include a target straight section whose continuous straight travel distance is smaller than the threshold, the target straight section being a section in which one or more straight links are arranged continuously between two curved links, and the continuous straight travel distance being a length of the target straight section.

An average travel speed of the transport vehicle is likely to be higher as a distance by which the transport vehicle can continuously travel straight becomes longer, and the average travel speed of the transport vehicle is likely to be lower as this distance becomes shorter. According to this configuration, the cost correction amount is derived such that, if the candidate route includes such a section having a relatively short continuous straight travel distance, the route cost of the candidate route becomes larger than the route cost of a candidate route that does not include such a section. Therefore, according to this configuration, in the route selection processing, a candidate route for which the average travel speed of the transport vehicle is likely to be low is unlikely to be selected, and a candidate route for which the average travel speed of the transport vehicle is likely to be high is likely to be selected. Therefore, it is possible to select an appropriate route taking the shape of the route formed by the plurality of links into consideration.

It is preferable that a straight line distance is set for each straight link, the straight line distance being a length of the straight link, and
the standard cost of each straight link is set based on at least the straight line distance.

As the straight link becomes longer, the time it takes for the transport vehicle to pass through the straight link is likely to become longer, and accordingly, the standard cost is likely to become larger. According to this configuration, the standard cost of the straight link is set to become larger as the straight line distance of the straight link becomes longer. Therefore, it is possible to appropriately set the standard cost of the straight link.

It is preferable that the cost correction amount is derived for each target straight section in the cost correction amount deriving processing, and
in the route selection processing, the route cost of each candidate route is calculated based on a value obtained by correcting a target straight section standard cost of each target straight section included in the candidate route with the cost correction amount derived for each target straight section, the target straight section standard cost being a sum of the standard costs of all links included in the target straight section.

According to this configuration, if a candidate route includes a plurality of target straight sections, the cost correction amount is derived for each of the target straight sections, and accordingly, it is possible to appropriately calculate the route cost of such a candidate route.

### INDUSTRIAL APPLICABILITY

The technology according to the present disclosure is applicable to an article transport facility that includes a predetermined route, a transport vehicle that travels along the route and transports an article, and a control system that designates a movement destination and a movement route to the movement destination with respect to the transport vehicle.

What is claimed is:

1. An article transport facility comprising:
a predetermined route;
a transport vehicle configured to travel along the route and transport an article; and
a control system configured to designate, with respect to the transport vehicle, a movement destination and a movement route to the movement destination, and
wherein:
the route comprises a plurality of nodes and a plurality of links connecting adjacent nodes among the nodes to each other,
the article transport facility is configured to set in advance, for each of the plurality of links, a standard cost corresponding to a time it takes for the transport vehicle to pass through that link, and
the control system is configured to execute:
route extraction processing for extracting a plurality of candidate routes that are candidates for the route along which the transport vehicle is capable of moving from a movement origin to the movement destination by referring to map information that is information regarding the route;
cost correction amount deriving processing for deriving, with respect to each of the plurality of candidate routes, a cost correction amount of the candidate route based on a combination of shapes of the plurality of links included in the candidate route; and
route selection processing for selecting a candidate route having a smallest route cost out of the plurality of candidate routes, as the movement route of the transport vehicle, by calculating a route cost of each candidate route based on a sum of the standard costs of all links included in the candidate route and the cost correction amount determined for that candidate route in the cost correction amount deriving processing.

2. The article transport facility according to claim 1,
wherein the links comprise one or more straight links and one or more curved links, and
wherein the cost correction amount is derived in the cost correction amount deriving processing such that, if a candidate route includes a target straight section whose continuous straight travel distance is smaller than a predetermined threshold, the route cost of that candidate route becomes larger than the route cost of a candidate route that does not include a target straight section whose continuous straight travel distance is smaller than the threshold, the target straight section is a section in which one or more straight links are arranged continuously between two curved links, and the continuous straight travel distance is a length of the target straight section.

3. The article transport facility according to claim 2,
wherein a straight line distance is set for each straight link, and the straight line distance is a length of the straight link, and
wherein the standard cost of each straight link is set based on at least the straight line distance.

4. The article transport facility according to claim 2,
wherein the cost correction amount is derived for each target straight section in the cost correction amount deriving processing, and
wherein, in the route selection processing, the route cost of each candidate route is calculated based on a value obtained by correcting a target straight section standard cost of each target straight section included in the candidate route with the cost correction amount derived for each target straight section, and the target straight section standard cost is a sum of the standard costs of all links included in the target straight section.
